(19) United States
(12) Patent Application Publication
(10) Pub. No.: US 2019/0260332 A1
(43) Pub. Date: Aug. 22, 2019

(54) METHOD FOR ATTACHING CONNECTOR TO SOLAR CELL ELECTRODES IN A SOLAR ROOF TILE

(71) Applicant: TESLA, INC., Palo Alto, CA (US)

(72) Inventor: Bobby Yang, Dublin, CA (US)

(73) Assignee: TESLA, INC., Palo Alto, CA (US)

(21) Appl. No.: 15/900,600

(22) Filed: Feb. 20, 2018

(51) Int. Cl. H02S 40/34; H02S 20/25; H01L 31/02; H01R 25/14

(52) U.S. Cl. CPC H02S 40/34; H01R 25/142; H01L 31/0201; H02S 20/25

(57) ABSTRACT

One embodiment can provide a photovoltaic roof tile. The photovoltaic roof tile can include a plurality of photovoltaic structures positioned between a front cover and a back cover and at least one external conductive connector coupled to a busbar belonging to a photovoltaic structure. The external conductive connector is electrically and mechanically coupled to the busbar via an electrically conductive adhesive (ECA) paste.

### FIELD

This disclosure is generally related to photovoltaic (or “PV”) roof tiles. More specifically, this disclosure is related to a system and method for attaching inter-tile electrical connectors to existing electrodes of photovoltaic structures.

### RELATED ART

In residential and commercial solar energy installations, a building's roof typically is installed with photovoltaic (PV) modules, also called PV or solar panels, that can include a two-dimensional array (e.g., 6×12) of solar cells. A PV roof tile (or solar roof tile) can be a particular type of PV module offering weather protection for the home and a pleasing aesthetic appearance, while also functioning as a PV module to convert solar energy to electricity. The PV roof tile can be shaped like a conventional roof tile and can include one or more solar cells encapsulated between a front cover and a back cover, but typically enclose fewer solar cells than a conventional solar panel. The front and back covers can be fortified glass or other material that can protect the PV cells from the weather elements. Note that a typical roof tile may have a dimension of 15 in×8 in =120 in²=774 cm², and a typical solar cell may have a dimension of 6 in×6 in =36 in²=232 cm². Similar to a conventional PV panel, the PV roof tile can include an encapsulating layer, such as an organic polymer. A lamination process can seal the solar cells between the front and back covers. Like conventional PV panels, electrical interconnections are needed within each PV roof tile and among different roof tiles.

### SUMMARY

One embodiment can provide a photovoltaic roof tile. The photovoltaic roof tile can include a plurality of photovoltaic structures positioned between a front cover and a back cover and at least one external conductive connector coupled to a busbar belonging to a photovoltaic structure. The external conductive connector is electrically and mechanically coupled to the busbar via an electrically conductive adhesive (ECA) paste.

In a variation on this embodiment, a respective photovoltaic structure can include a first edge busbar positioned near an edge of a first surface and a second edge busbar positioned near an opposite edge of a second surface. The plurality of photovoltaic structures can be arranged in such a way that the first edge busbar of a first photovoltaic structure overlaps the second edge busbar of an adjacent photovoltaic structure, thereby resulting in the plurality of photovoltaic structures forming a serially coupled string.

In a further variation, the at least one conductive connector can be coupled to an edge busbar positioned at an end of the serially coupled string.

In a variation on this embodiment, the external conductive connector can include a copper core layer, a protective layer surrounding the copper core layer, and a masking layer on a surface of the protective layer.

In a further variation on this embodiment, the protective layer can include one or more of: Sn, Pb, Ag, and Sb.

In a further variation, the masking layer can include an acrylic paint layer.

In a variation on this embodiment, the ECA paste can include conductive particles suspended in a resin or a solder paste.

In a variation on this embodiment, the external conductive connector can include a strain-relief connector.

In a further variation, the strain-relief connector can include an elongated connection member, a number of curved metal wires, laterally extended from one side of the elongated connection member, and a number of connection pads.

In a further variation, the ECA paste is positioned between the connection pads and the busbar, forming an electrical and mechanical bond.

One embodiment can provide a method for fabricating a photovoltaic roof tile. The fabrication method can include forming a cascaded string of photovoltaic structures, forming an external conductive connector, attaching, using an electrically conductive adhesive (ECA) paste, the external conductive connector to a busbar belonging to a photovoltaic structure within the cascaded string of photovoltaic structures, and laminating the cascaded string of photovoltaic structures and the attached external conductive connector between a front cover and a back cover.

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BRIEF DESCRIPTION OF THE FIGURES

FIG. 1 shows an exemplary configuration of photovoltaic roof tiles on a house.

FIG. 2 shows the perspective view of an exemplary photovoltaic roof tile, according to an embodiment.

FIG. 3 shows a cross-section of an exemplary photovoltaic roof tile, according to an embodiment.

FIG. 4A illustrates an exemplary configuration of a multi-tile module, according to one embodiment.

FIG. 4B illustrates a cross-section of an exemplary multi-tile module, according to one embodiment.

FIG. 5A illustrates a serial connection between three adjacent cascaded photovoltaic strips, according to one embodiment.

FIG. 5B illustrates the side view of the string of cascaded strips, according to one embodiment.

FIG. 6A shows the top view of an exemplary multi-tile module, according to one embodiment.

FIG. 6B shows the top view of an exemplary multi-tile module, according to one embodiment.

FIG. 7A shows a detailed view of an exemplary strain-relief connector, according to one embodiment.

FIG. 7B illustrates the coupling between a strain-relief connector and the front side of a photovoltaic structure, according to one embodiment.

FIG. 7C illustrates the coupling between a strain-relief connector and the back side of a photovoltaic structure, according to one embodiment.

FIG. 8A presents a cross-sectional view of the interface between the strain-relief connector and the PV structure busbar.

FIG. 8B illustrates the phenomenon of solder reflow.

FIG. 9 presents a cross-sectional view of the interface between an external electrical connector and a PV structure busbar, according to one embodiment.

FIG. 10 presents a flowchart illustrating an exemplary process for fabricating a photovoltaic module, according to an embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

Overview

Embodiments described herein provide a solution to the technical problem of enabling reliable electrical coupling between a metallic (e.g., Cu) connector and an existing electrode on a photovoltaic structure during the fabrication of a PV roof tile. More specifically, instead of solder as in conventional approaches, electrically conductive adhesive (ECA) paste can be used to bond the metallic connector (e.g., a Cu connector) to an existing electrode (e.g., a busbar) on the photovoltaic structure. Moreover, the metallic connector can be coated with a protective layer (e.g., a layer of solder) to protect it from oxidation and corrosion. The ECA can include a solder paste and can be cured at a temperature (e.g., 143° C.) below the melting point of the solder coating (e.g., 183° C.), thereby preventing reflow of the solder and/or damage to the photovoltaic structure. Compared to solder-based bonding, ECA-based bonding can be more reliable, especially in situations where an acrylic paint coating is applied on top of the metallic connector for aesthetic purposes.

PV Roof Tile Modules with Electrical Interconnects

A PV roof tile (or solar roof tile) is a type of PV module shaped like a roof tile and typically enclosing fewer solar cells than a conventional solar panel. Note that such PV roof tiles can function as both PV cells and roof tiles at the same time. PV roof tiles and modules are described in more detail in U.S. Provisional Patent Application No. 62/465,694, Attorney Docket Number P357-1PUS, entitled “SYSTEM AND METHOD FOR PACKAGING PHOTOVOLTAIC ROOF TILES” filed Mar. 1, 2017, which is incorporated herein by reference. In some embodiments, the system disclosed herein can be applied to PV roof tiles and/or other types of PV module.

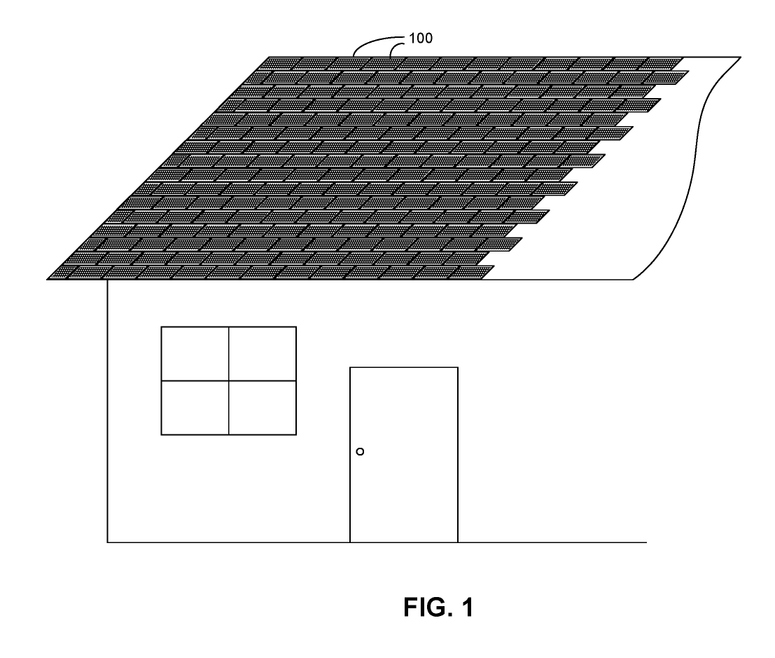

FIG. 1 shows an exemplary configuration of PV roof tiles on a house. PV roof tiles 100 can be installed on a house like conventional roof tiles or shingles. Particularly, a PV roof tile can be placed with other tiles in such a way as to prevent water from entering the building.

A PV roof tile can enclose multiple solar cells or PV structures, and a respective PV structure can include one or more electrodes such as busbars and finger lines. The PV structures within a PV roof tile can be electrically and optionally mechanically coupled to each other. For example, multiple PV structures can be electrically coupled together by a metallic tab, via their respective busbars, to create serial or parallel connections. Moreover, electrical connections can be made between two adjacent tiles, so that a number of PV roof tiles can jointly provide electrical power.

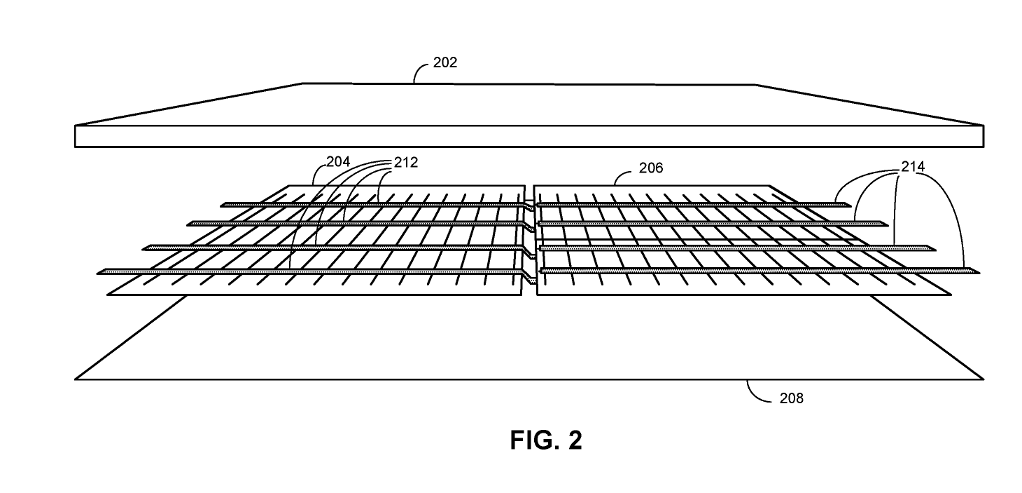

FIG. 2 shows the perspective view of an exemplary photovoltaic roof tile, according to an embodiment. Solar cells 204 and 206 can be hermetically sealed between top glass cover 202 and backsheet 208, which jointly can protect the solar cells from various weather elements. In the example shown in FIG. 2, metallic tabbing strips 212 can be in contact with the front-side electrodes of solar cell 204 and extend beyond the left edge of glass 202, thereby serving as contact electrodes of a first polarity of the PV roof tile. Tabbing strips 212 can also be in contact with the back side of solar cell 206, creating a serial connection between solar cell 204 and solar cell 206. On the other hand, tabbing strips 214 can be in contact with front-side electrodes of solar cell 206 and extend beyond the right edge of glass cover 202, serving as contact electrodes of a second polarity of the PV roof tile.

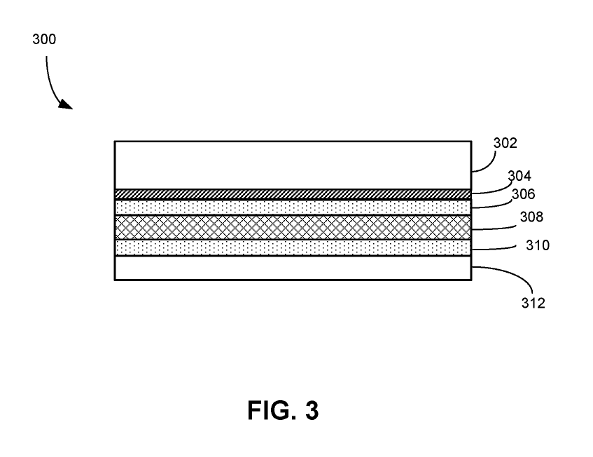

FIG. 3 shows a cross-section of an exemplary photovoltaic roof tile, according to an embodiment. Solar cell or array of solar cells 308 can be encapsulated between top glass cover 302 and back cover 312, which can be fortified glass or a regular PV backsheet. Top encapsulant layer 306, which can be based on a polymer, can be used to seal top glass cover 302 and solar cell or array of solar cells 308. Specifically, encapsulant layer 306 may include polyvinyl butyral (PVB), thermoplastic polyolefin (TPO), ethylene vinyl acetate (EVA), or N,N′-diphenyl-N,N′-bis(3-methylphenyl)-1,1′-diphenyl-4,4′-diamine (TPD). Similarly, lower encapsulant layer 310, which can be based on a similar material, can be used to seal array of solar cells 308 and back cover 312. A PV roof tile can also contain other optional layers, such as an optical filter or coating layer or a layer of nanoparticles for providing desired color appearances. In the example of FIG. 3, module or roof tile 300 also contains an optical filter layer 304.

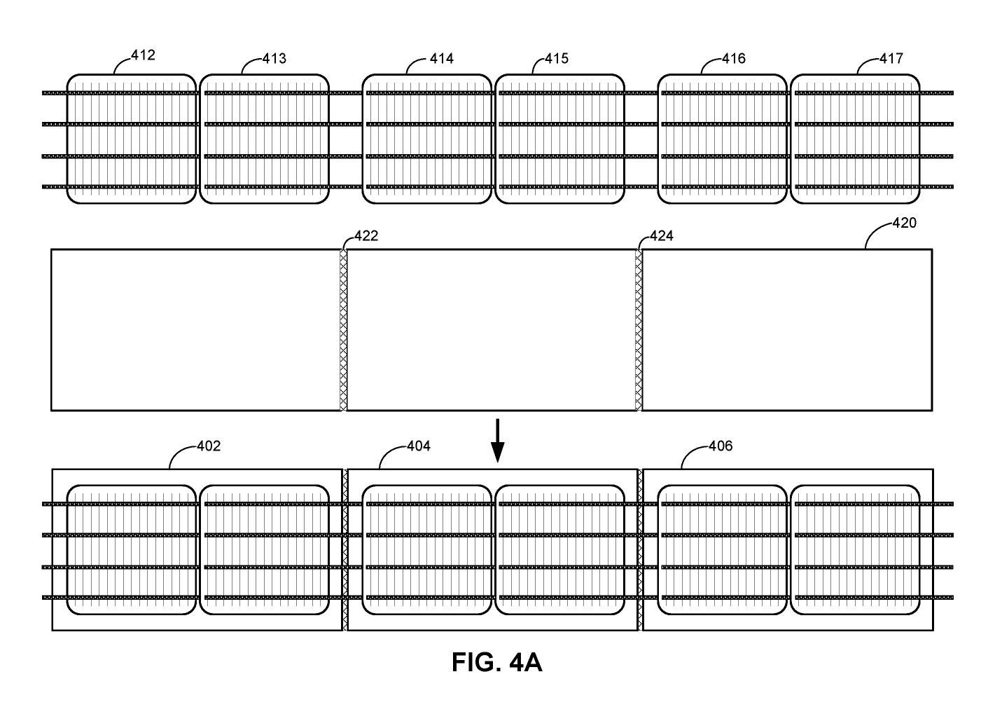

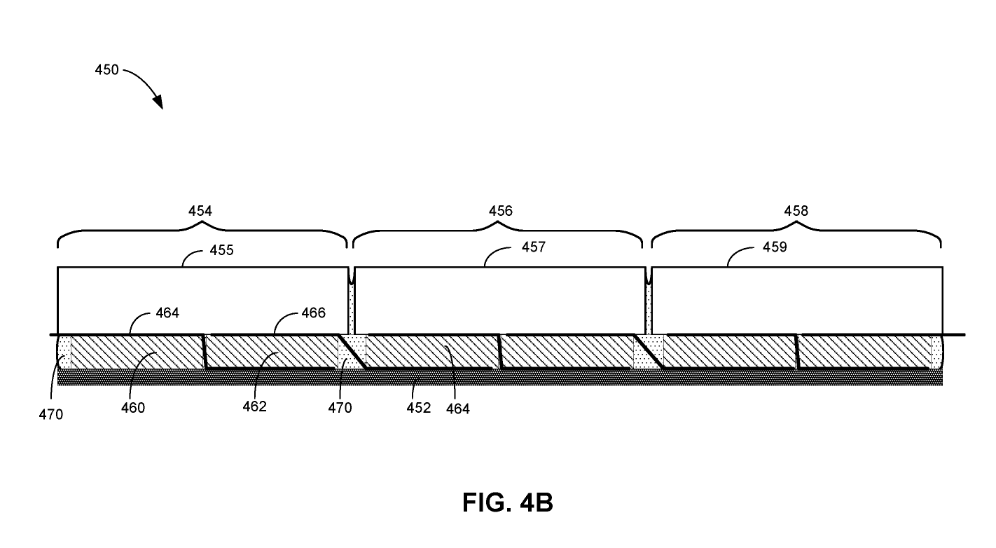

To facilitate more scalable production and easier installation, multiple photovoltaic roof tiles can be fabricated together, while the tiles are linked in a rigid or semi-rigid way. FIG. 4A illustrates an exemplary configuration of a multi-tile module, according to one embodiment. In this example, three PV roof tiles 402, 404, and 406 can be manufactured together. During fabrication, solar cells 412 and 413 (corresponding to tile 402), 414 and 415 (corresponding to tile 404), and 416 and 417 (corresponding to tile 406) can be laid out with tabbing strips interconnecting their corresponding busbars, forming a connection in series. Furthermore, these six solar cells can be laid out on a common backsheet. Subsequently, front-side glass cover 420 can be sealed onto these six PV cells.

It is possible to use a single piece of glass as glass cover 420. In one embodiment, grooves 422 and 424 can be made on glass cover 420, so that the appearance of three separate roof tiles can be achieved. It is also possible to use three separate pieces of glass to cover the six cells, which are laid out on a common backsheet. In this case, gaps 422 and 424 can be sealed with an encapsulant material, establishing a semi-rigid coupling between adjacent tiles. Prefabricating multiple tiles into a rigid or semi-rigid multi-tile module can significantly reduce the complexity in roof installation, because the tiles within the module have been connected with the tabbing strips. Note that the numbers of tiles included in each multi-tile module can be more or fewer than what is shown in FIG. 4A.

FIG. 4B illustrates a cross-section of an exemplary multi-tile module, according to one embodiment. In this example, multi-tile module 450 can include photovoltaic roof tiles 454, 456, and 458. These tiles can share common backsheet 452, and have three individual glass covers 455, 457, and 459, respectively. Each tile can encapsulate two solar cells. For example, tile 454 can include solar cells 460 and 462 encapsulated between backsheet 452 and glass cover 455. Tabbing strips can be used to provide electrical coupling within each tile and between adjacent tiles. For example, tabbing strip 464 can couple the front electrode of solar cell 460 to the back electrode of solar cell 462, creating a serial connection between these two cells. Similarly, tabbing strip 466 can couple the front electrode of cell 462 to the back electrode of cell 464, creating a serial connection between tile 454 and tile 456.

The gap between two adjacent PV tiles can be filled with encapsulant, protecting tabbing strips interconnecting the two adjacent tiles from the weather elements. For example, encapsulant 470 fills the gap between tiles 454 and 456, protecting tabbing strip 466 from weather elements. Furthermore, the three glass covers, backsheet 452, and the encapsulant together form a semi-rigid construction for multi-tile module 450. This semi-rigid construction can facilitate easier installation while providing a certain degree of flexibility among the tiles.

In addition to the examples shown in FIGS. 4A and 4B, a PV tile may include different forms of photovoltaic structures. For example, in order to reduce internal resistance, each square solar cell shown in FIG. 4A can be divided into multiple (e.g., three) smaller strips, each having edge busbars of different polarities on its two opposite edges. The edge busbars allow the strips to be cascaded one by one to form a serially connected string.

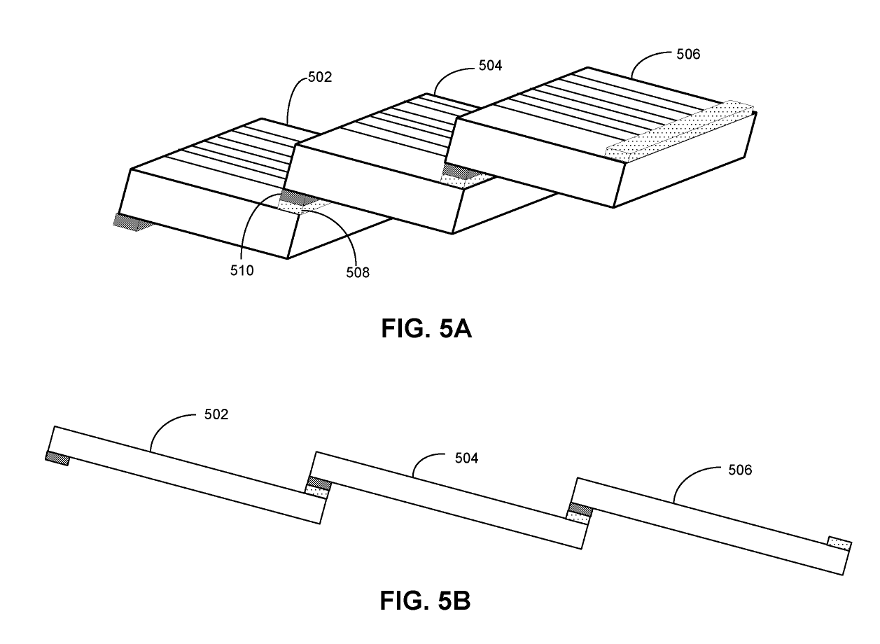

FIG. 5A illustrates a serial connection between three adjacent cascaded photovoltaic strips, according to one embodiment. In FIG. 5A, strips 502, 504, and 506 are stacked in such a way that strip 504 partially overlaps adjacent strip 506 to its right, and strip 502 to its left. The resulting string of strips forms a cascaded pattern similar to roof shingles. Strips 502 and 504 are electrically coupled in series via edge busbar 508 at the top surface of strip 502 and edge busbar 510 at the bottom surface of strip 504. Strips 502 and 504 can be arranged in such a way that bottom edge busbar 510 is above and in direct contact with top edge busbar 508. The coupling between strips 504 and 506 can be similar.

FIG. 5B illustrates the side view of the string of cascaded strips, according to one embodiment. In the example shown in FIGS. 5A and 5B, the strips can be segments of a six-inch square or pseudo-square solar cell, with each strip having a dimension of approximately two inches by six inches. To reduce shading, the overlapping between adjacent strips should be kept as small as possible. Therefore, in the example shown in FIGS. 5A and 5B, the single busbars (both at the top and the bottom surfaces) can be placed at or near the very edge of the strip. The same cascaded pattern can extend along multiple strips to form a serially connected string, and a number of strings can be coupled in series or parallel.

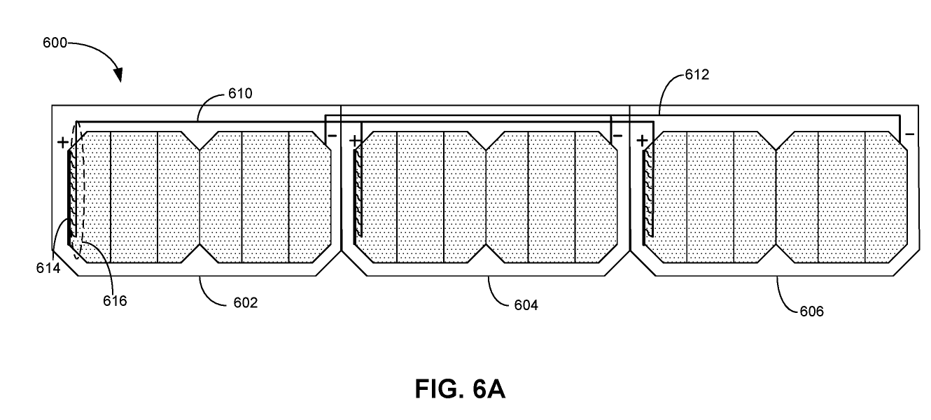

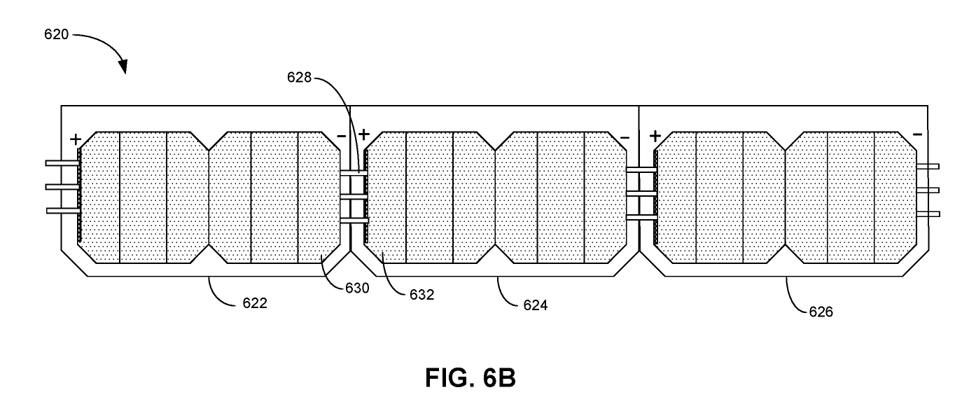

FIG. 6A shows the top view of an exemplary multi-tile module, according to one embodiment. Multi-tile module 600 can include PV roof tiles 602, 604, and 606 arranged side by side. Each PV roof tile can include six cascaded strips encapsulated between the front and back covers, meaning that busbars located at opposite edges of the cascaded string of strips have opposite polarities. For example, if the leftmost edge busbar of the strips in PV roof tile 602 has a positive polarity, then the rightmost edge busbar of the strips will have a negative polarity. Serial connections can be established among the tiles by electrically coupling busbars having opposite polarities, whereas parallel connections can be established among the tiles by electrically coupling busbars having the same polarity.

In the example shown in FIG. 6A, the PV roof tiles are arranged in such a way that their sun-facing sides have the same electrical polarity. As a result, the edge busbars of the same polarity will be on the same left or right edge. For example, the leftmost edge busbar of all PV roof tiles can have a positive polarity and the rightmost edge busbar of all PV roof tiles can have a negative polarity, or vice versa. In FIG. 6A, the left edge busbars of all strips have a positive polarity (indicated by the “+” signs) and are located on the sun-facing (or front) surface of the strips, whereas the right edge busbars of all strips have a negative polarity (indicated by the “−” signs) and are located on the back surface. Depending on the design of the layer structure of the solar cell, the polarity and location of the edge busbars can be different from those shown in FIG. 6A.

A parallel connection among the tiles can be formed by electrically coupling all leftmost busbars together via metal tab 610 and all rightmost busbars together via metal tab 612. Metal tabs 610 and 612 are also known as connection buses and typically can be used for interconnecting individual solar cells or strings. A metal tab can be stamped, cut, or otherwise formed from conductive material, such as copper. Copper is a highly conductive and relatively low-cost connector material. However, other conductive materials such as silver, gold, or aluminum can be used. In particular, silver or gold can be used as a coating material to prevent oxidation of copper or aluminum. In some embodiments, alloys that have been heat treated to have super-elastic properties can be used for all or part of the metal tab. Suitable alloys may include, for example, copper-zinc-aluminum (CuZnAl), copper-aluminum-nickel (CuAlNi), or copper-aluminum-beryllium (CuAlBe). In addition, the material of the metal tabs disclosed herein can be manipulated in whole or in part to alter mechanical properties. For example, all or part of metal tabs 610 and 612 can be forged (e.g., to increase strength), annealed (e.g., to increase ductility), and/or tempered (e.g. to increase surface hardness).

The coupling between a metal tab and a busbar can be facilitated by a specially designed strain-relief connector. In FIG. 6A, strain-relief connector 616 can be used to couple busbar 614 and metal tab 610. Such strain-relief connectors are needed due to the mismatch of the thermal expansion coefficients between metal (e.g., Cu) and silicon. As shown in FIG. 6A, the metal tabs (e.g., tabs 610 and 612) may cross paths with strain-relief connectors of opposite polarities. To prevent an electrical short of the photovoltaic strips, portions of the metal tabs and/or strain-relief connectors can be coated with an insulation film or wrapped with a sheet of insulation material.

In some embodiments, instead of parallelly coupling the tiles within a tile module as shown in FIG. 6A, one can also form serial coupling among the tiles. FIG. 6B shows the top view of an exemplary multi-tile module, according to one embodiment. Tile module 620 can include solar roof tiles 622, 624, and 626. Each tile can include a number (e.g., six) of cascaded solar cell strips arranged in a manner shown in FIGS. 5A and 5B. Furthermore, metal tabs can be used to interconnect photovoltaic strips enclosed in adjacent tiles. For example, metal tab 628 can connect the front side of strip 632 with the back side of strip 630, creating a serial coupling between strips 630 and 632. Although the example in FIG. 6B shows three metal tabs interconnecting the photovoltaic strips, other numbers of metal tabs can also be used. Furthermore, each solar roof tile can contain fewer or more cascaded strips, which can be of various shapes and sizes.

In all of the examples shown in FIGS. 4A-4B and 6A-6B, electrical coupling is needed between metallic tabs/strips external to the photovoltaic structures and metallic busbars that are part of the photovoltaic structures. Conventionally, electrical interconnections within a PV module (e.g., a conventional roof top PV panel) may be achieved by soldering metallic tabs or strips onto surface busbars of solar cells. However, such an approach can be problematic in PV roof tile applications. First, compared to electrical interconnections within conventional PV panels, electrical interconnections within a PV roof tile module may experience a higher amount of stress due to possible position shifts between individual PV roof tiles. The solder-based coupling may be too rigid to withhold such stress. Second, to achieve desired aesthetic effects, exposed surfaces of electrical interconnections (e.g., the metallic connectors) embedded with PV roof tiles may have been coated with a layer of acrylic paint, typically on top of a solder layer, which is used for prevention of corrosion and oxidation. For example, in FIG. 6A, the sun-facing surface of metal tabs 610 and 612 and the strain-relief connectors (e.g., strain-relief connector 616) have been coated with a layer of masking material (e.g., acrylic paint) to ensure that these metal parts have a similar appearance as other parts of the roof tile. However, the process to create a solder-based electrical coupling often involves subjecting the metallic connectors to high temperatures to cause solder reflow. The reflow of the solder can damage the overlaying masking layer.

### Electrical Conductors in PV Tile Modules

As described previously, an individual PV structure can include built-in electrodes, such as busbars and finger lines. To output power and to electrically connect to other PV structures or modules, the built-in electrodes (particularly the busbars) of a PV structure need to connect to built-in electrodes of other PV structures or external electrical connectors.

More specifically, FIGS. 5A-5B show the electrical coupling between adjacent PV structures, where edge busbars belonging to different PV structures can be stacked against each other to make contact. The electrical and mechanical coupling between two overlapping busbars can be achieved by soldering or by applying conductive paste. In some embodiments, conductive paste can be used to provide electrical and mechanical bonding between the overlapping busbars. Detailed descriptions regarding forming a cascaded string of PV structures using conductive paste can be found in U.S. patent application Ser. No. 14/866,806, entitled “METHODS AND SYSTEMS FOR PRECISION APPLICATION OF CONDUCTIVE ADHESIVE PASTE ON PHOTOVOLTAIC STRUCTURES,” filed Sep. 25, 2015, the disclosure of which is incorporated herein by reference in its entirety.

In addition to coupling among different PV structures, electrical coupling among different PV roof tiles is also important and requires careful consideration. Unlike direct busbar-to-busbar coupling, electrical coupling between two different PV roof tiles often requires coupling between the PV structure busbar and an external connector, typically a metallic connector. In some embodiments, such a metallic connector can be a specially designed strain-relief connector, such as connector 616 shown in FIG. 6A.

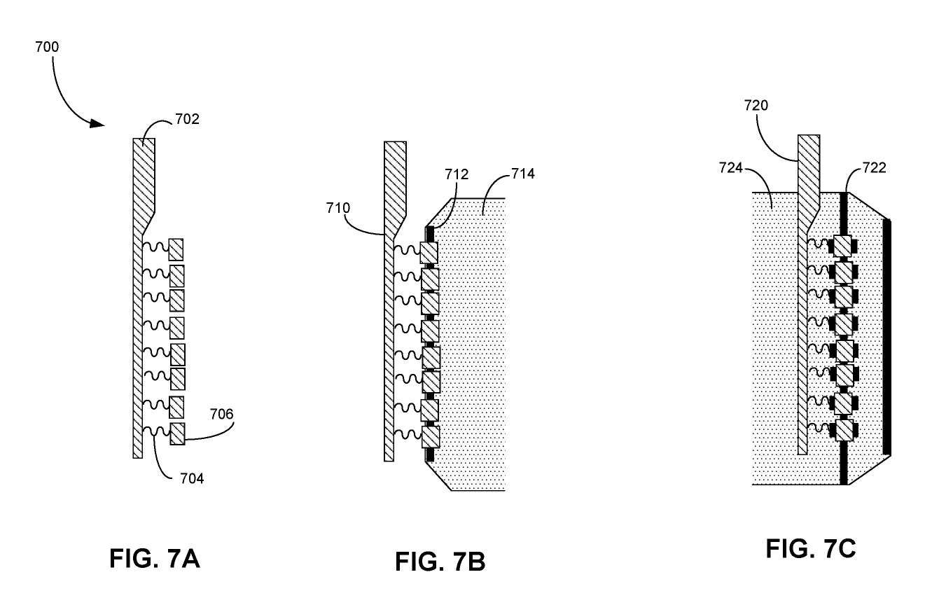

FIG. 7A shows a detailed view of an exemplary strain-relief connector, according to one embodiment. In FIG. 7A, strain-relief connector 700 can include elongated connection member 702, a number of curved metal wires (e.g., curved metal wire 704), and a number of connection pads (e.g., connection pad 706). Elongated connection member 702 can extend along a direction substantially parallel to the to-be-coupled busbar of a photovoltaic structure. The curved metal wires can extend laterally from elongated connection member 702. These curved wires can relieve the strain generated due to the mismatch of thermal expansion coefficient between the metal connector and the Si-based photovoltaic structure. In some embodiments, each curved metal wire can be attached to a connection pad. For example, curved metal wire 704 can be attached to connection pad 706. In alternative embodiments, more than one (e.g., two or three) curved wires can be attached to a connection pad. The elongated connection member 702, the curved wires, and the connection pads can be formed (e.g., stamped or cut) from a single piece of material, or they can be attached to each other by any suitable electrical connection, such as by soldering, welding, or bonding.

FIG. 7B illustrates the coupling between a strain-relief connector and the front side of a photovoltaic structure, according to one embodiment. More specifically, strain-relief connector 710 is coupled to edge busbar 712 of photovoltaic structure 714 by overlapping its connection pads with the front side of edge busbar 712.

FIG. 7C illustrates the coupling between a strain-relief connector and the back side of a photovoltaic structure, according to one embodiment. More specifically, strain-relief connector 720 is coupled to busbar 722 of photovoltaic structure 724 by overlapping its connection pads with contact pads belonging to busbar 722. Note that, unlike the front side, the back side of a photovoltaic structure can include additional busbars because there is no need to worry about shading on the back side. To facilitate better adhesion and electrical access, the additional busbars on the back side of the PV structure can also include widened regions, known as contact pads. Detailed descriptions of such contact pads can be found in U.S. patent application Ser. No. 14/831,767, Attorney Docket Number SCTY-P142-1NUS, filed Aug. 20, 2015 and entitled “Photovoltaic Electrode Design with Contact Pads for Cascaded Application,” the disclosure of which is incorporated herein by reference in its entirety.

As shown in FIGS. 7B and 7C, the strain-relief connector needs to be bonded to the busbar (either the front side edge busbar or the back side busbar with contact pads) on the PV structure. One straightforward approach is to solder them together. In most cases, because the busbar and the strain-relief connector comprise Cu, to prevent corrosion and oxidation, the surfaces of the busbar and the strain-relief connector have been coated with a layer of soldering material (e.g., Pb/Sn or Pb/Sn/Sb alloy). Therefore, a solder-based bond between the strain-relief connector and the busbar can be achieved by simply heating up their interface to a temperature greater than or equal to the melting point of the solder and then removing the heat.

However, such soldering can require a relatively high temperature (e.g., 183° C. for Sn₆₂Pb₃₆Ag₂), which may cause several problems, including possible damage to the PV structures. Moreover, although only the bottom surface of the connection pads of the strain-relief connector needs to be soldered to the top surface of the PV structure busbar, the heat generated during the soldering process may cause the solder layer on other parts (e.g., the elongated connection member) of the strain-relief connector to reflow, generating undesired effects.

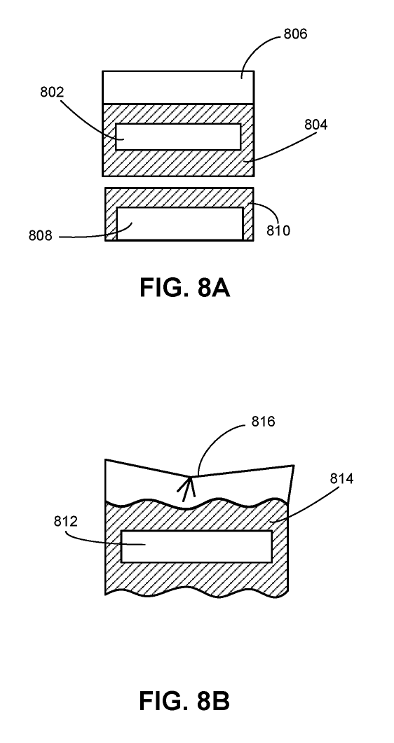

FIG. 8A presents a cross-sectional view of the interface between the strain-relief connector and the PV structure busbar. In FIG. 8A, strain-relief connector 802 can be coated with a solder layer 804, which can cover both the top and bottom surfaces of strain-relief connector 802. The top surface of strain-relief connector 802 can also be coated, over solder layer 804, with a masking layer 806, which can be used to prevent reflection of sunlight from the metallic connector and to achieve desired aesthetic effects. Masking layer 806 typically can include acrylic paint, which can have a dark color (e.g., black or blue). To achieve desired aesthetic effects, the color of masking layer 806 may be carefully designed to match the appearance of other portions of the PV roof tile.

On the other hand, the top surface and sidewalls of PV structure busbar 808 can also be covered by a solder layer 810. As one can see from FIG. 8A, strain-relief connector 802 and busbar 808 can be bonded to each other by joining solder layers 804 and 810 to each other. During soldering, the solder layer reflows, even at parts of the strain-relief connector that is not directly heated. FIG. 8B illustrates the phenomenon of solder reflow. In this example, portion 812 of a strain-relief connector is not directly heated during soldering. However, the surrounding solder layer 814 still reflows due to conductive heat. The reflow can cause deformation of solder layer 814, as shown in FIG. 8B. Because masking layer 816 is deposited on solder layer 814, the deformation of solder layer 814 can also cause deformation (e.g., cracking or peeling) of masking layer 816.

To solve this problem, in some embodiments, instead of a solder-based bond, the strain-relief connector (or any other type of external electrical connector) can be bonded to the busbar of the PV structure using electrically conductive adhesive (ECA). More specifically, ECA paste can create a strong mechanical coupling, while also being electrically conductive, and can be dispensed and cured at a lower temperature, thus preventing solder reflow as well as possible damage to the photovoltaic structure.

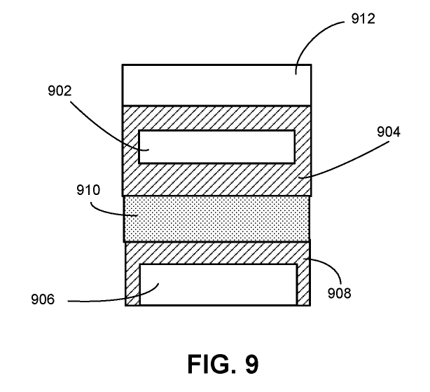

FIG. 9 presents a cross-sectional view of the interface between an external electrical connector and a PV structure busbar, according to one embodiment. In FIG. 9, both electrical connector 902 and busbar 906 can be inside a PV module, such as a PV roof tile. Electrical connector 902 can be external to PV structures, whereas busbar 906 can be built-in to a PV structure. External electrical connector 902 can be optionally coated with a protective layer 904 to prevent corrosion and oxidation. In some embodiments, external electrical connector 902 can be made of a metal with low resistivity, such as Cu. Protective layer 904 can include a solder layer or any other anti-corrosion coating. In some embodiments, protective layer 904 can include Sn- or Pb-based solder, such as Sn₆₂Pb₃₆Ag₂. Moreover, a masking layer 912 can be optionally deposited on the top surface of protective layer 904. Masking layer 912 can be configured to provide certain desired aesthetic effects, e.g., making electrical connector 902 similar in appearance to other portions of the PV module.

Busbar 906 can include various metallic materials with low resistivity, such as Cu. Busbar 906 can also be optionally coated with a protective layer 908, which can protect the sidewalls and top surface of busbar 906 against corrosion and oxidation. The bottom surface of busbar 906 is against the rest of the PV structure. To facilitate mechanical and electrical bonding, an ECA layer 910 can be deposited between electrical connector 902 and busbar 906. In some embodiments, ECA layer 910 can include particles of a conductive material (e.g., silver, copper, or graphite) suspended within an adhesive (e.g., a varnish or a synthetic resin). More specifically, ECA layer 910 can include conductive adhesive that can be different from the conductive paste used for bonding between edge busbars. More specifically, the conductive adhesive included in ECA layer 910 can be isotropic in nature, whereas the conductive paste used for bonding busbars is typically anisotropic. In alternative embodiments, the ECA can include solder paste, which can contain solder and flux. After curing, ECA layer 910 can create a strong, electrically conductive bond between electrical connector 902 and busbar 906.

In some embodiments, ECA layer 910 can be heat cured at a temperature that is sufficiently low that it does not cause solder reflow. For example, ECA layer 910 can be dispensed and cured at 143° C., which is much lower than the 183° C. required to reflow the Sn₆₂Pb₃₆Ag₂ solder. In some embodiments, ECA layer 910 can be cured at room temperature.

### Fabrication of a Photovoltaic Module

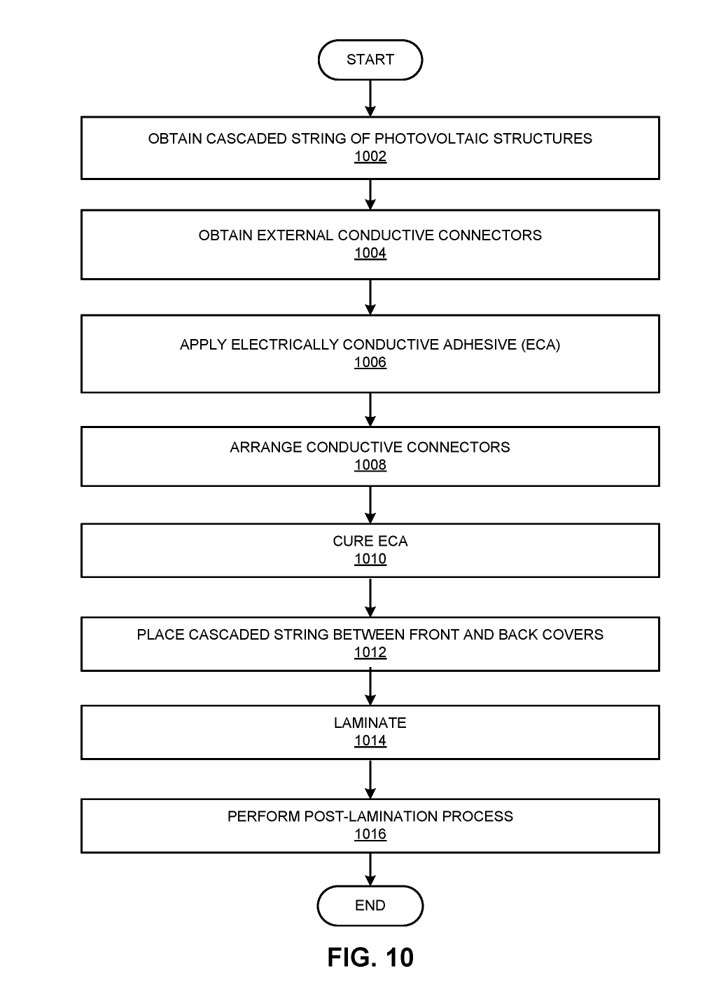

FIG. 10 presents a flowchart illustrating an exemplary process for fabricating a photovoltaic module, according to an embodiment. The photovoltaic module can be a PV roof tile. During fabrication, a cascaded string of photovoltaic structures can be obtained (operation 1002). More specifically, obtaining the cascaded string can involve dividing standard square solar cells into smaller strips, applying conductive paste on edge busbars, arranging the strips so that they overlap at the edge, and curing the conductive paste. Detailed descriptions about the formation of a cascaded string of photovoltaic strips can be found in U.S. patent application Ser. No. 14/826,129, Attorney Docket No. P103-3NUS, entitled “PHOTOVOLTAIC STRUCTURE CLEAVING SYSTEM,” filed Aug. 13, 2015; U.S. patent application Ser. No. 14/866,776, Attorney Docket No. P103-4NUS, entitled “SYSTEMS AND METHODS FOR CASCADING PHOTOVOLTAIC STRUCTURES,” filed Sep. 25, 2015; U.S. patent application Ser. No. 14/804,306, Attorney Docket No. P103-5NUS, entitled “SYSTEMS AND METHODS FOR SCRIBING PHOTOVOLTAIC STRUCTURES,” filed Jul. 20, 2015; U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed Sep. 25, 2015; and U.S. patent application Ser. No. 14/866,817, Attorney Docket No. P103-7NUS, entitled “SYSTEMS AND METHODS FOR TARGETED ANNEALING OF PHOTOVOLTAIC STRUCTURES,” filed Sep. 25, 2015; the disclosures of which are incorporated herein by reference in their entirety.

After cascading, only the busbars at either edge of the string of PV structures are exposed and accessible. In some embodiments, the backside of the PV structures can include additional non-edge busbars, which are also accessible.

One or more external conductive connectors can also be obtained (operation 1004). In some embodiments, the conductive connectors can be strain-relief connectors, as shown in FIG. 7A, and can include Cu. Obtaining the conductive connectors can include coating Cu tapes with a protective layer and a masking layer, and then stamping or cutting out Cu strips having the desired shape. Alternatively, stamping or cutting Cu tapes can occur prior to coating the Cu strips with the protective layer and masking layer. The protective layer can include corrosion-resistant materials, including common materials, such as Sn, Sb, Pb, Ag, etc. The masking layer can include material that can change the color of the conductive connectors while being able to sustain long-time sun exposure, such as acrylic paint. The color of the acrylic paint can be chosen to match the color of the rest of the PV module. For example, if an optical filter deposited on the glass cover or on the surface of the PV structure can be configured to create a certain color effect (e.g., a red or orange hue), the acrylic paint deposited onto the conductive collectors needs to create a similar color effect.

Subsequently, a layer of ECA can be applied on a surface of the conductive connectors that is not coated with the masking layer, the surface of the exposed busbars, or both (operation 1006). In some embodiments, the ECA can include a conductive material (e.g., metal particles) and an adhesive, or can include solder paste, which can include powder of metal solder suspended in flux. The conductive connectors can then be arranged such that direct contact can be made between the connectors and the to-be-coupled busbars (operation 1008). In some embodiments, connection pads of the conductive connectors can be placed on top of the busbars. The ECA can then be cured (operation 1010). In some embodiments, heat can be applied locally (e.g., via radiation) to cure the ECA at a temperature that is lower than a threshold temperature for melting the solder. For example, the ECA can be cured at 143° C. Because the cascaded string of PV structures has two polarities, operations 1006-1010 may need to be performed twice to adhere a pair of external connectors to two busbars (one on the front side and one on the back side). Alternatively, each operation can be performed for both external connectors simultaneously.

The cascaded string of PV structures along with the attached external connectors can then be placed between a front cover and a back cover, embedded in encapsulant (operation 1012). A lamination operation can be performed to encapsulate the string of PV structures along with the attached external connectors inside the front and back covers (operation 1014). A post-lamination process (e.g., trimming of overflowed encapsulant and attachment of other roofing components) can then be performed to complete the fabrication of a PV roof tile (operation 1016).

In some embodiments, instead of a single roof tile, multiple tiles can be fabricated together to form a multi-tile module. In such a scenario, inter-tile electrical couplings are also need. More specifically, external connectors of a PV tile may need to be coupled to external connectors of adjacent PV tiles. To prevent paint cracking caused by solder reflow, the coupling between external connectors can also be achieved using ECA.

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

What is claimed is:

1. A photovoltaic roof tile, comprising:
a plurality of photovoltaic structures positioned between a front cover and a back cover; and
at least one external conductive connector coupled to a busbar belonging to a photovoltaic structure, wherein the external conductive connector is electrically and mechanically coupled to the busbar via an electrically conductive adhesive (ECA) paste.

2. The photovoltaic roof tile of claim 1, wherein a respective photovoltaic structure comprises a first edge busbar positioned near an edge of a first surface and a second edge busbar positioned near an opposite edge of a second surface, and wherein the plurality of photovoltaic structures is arranged in such a way that the first edge busbar of a first photovoltaic structure overlaps the second edge busbar of an adjacent photovoltaic structure, thereby resulting in the plurality of photovoltaic structures forming a serially coupled string.

3. The photovoltaic roof tile of claim 2, wherein the at least one external conductive connector is coupled to an edge busbar positioned at an end of the serially coupled string.

4. The photovoltaic roof tile of claim 1, wherein the external conductive connector comprises a copper core layer, a protective layer surrounding the copper core layer, and a masking layer on a surface of the protective layer.

5. The photovoltaic roof tile of claim 4, wherein the protective layer comprises one or more of: Sn, Pb, Ag, and Sb.

6. The photovoltaic roof tile of claim 4, wherein the masking layer comprises an acrylic paint layer.

7. The photovoltaic roof tile of claim 1, wherein the ECA paste comprises:
conductive particles suspended in a resin; or
a solder paste.

8. The photovoltaic roof tile of claim 1, wherein the external conductive connector comprises a strain-relief connector.

9. The photovoltaic roof tile of claim 8, wherein the strain-relief connector comprises:
an elongated connection member;
a number of curved metal wires, laterally extended from one side of the elongated connection member; and
a number of connection pads.

10. The photovoltaic module of claim 9, wherein the ECA paste is positioned between the connection pads and the busbar, forming an electrical and mechanical bond.

11. A method for fabricating a photovoltaic roof tile, the method comprising:
forming a cascaded string of photovoltaic structures;
forming an external conductive connector;
attaching, using an electrically conductive adhesive (ECA) paste, the external conductive connector to a busbar belonging to a photovoltaic structure within the cascaded string of photovoltaic structures; and
laminating the cascaded string of photovoltaic structures and the attached external conductive connector between a front cover and a back cover.

12. The method of claim 11, wherein a respective photovoltaic structure comprises a first edge busbar positioned near an edge of a first surface and a second edge busbar positioned near an opposite edge of a second surface, and wherein forming the cascaded string comprises arranging the photovoltaic structures in such a way that the first edge busbar of a first photovoltaic structure overlaps the second edge busbar of an adjacent photovoltaic structure, thereby creating a serial coupling between the photovoltaic structures.

13. The method of claim 12, wherein attaching the external conductive connector comprises attaching the conductive connector to an edge busbar positioned at an end of the cascaded string.

14. The method of claim 11, wherein forming the external conductive connector comprises:
coating a copper tape with a protective layer, wherein the protective layer covers all surfaces of the copper tape;
depositing a masking layer on a portion of the protective layer covering a first surface of the copper tape; and
stamping out the external conductive connector from the copper tape.

15. The method of claim 14, wherein the protective layer comprises one or more of: Sn, Pb, Ag, and Sb.

16. The method of claim 14, wherein the masking layer comprises an acrylic paint layer.

17. The method of claim 11, wherein the ECA paste comprises:
conductive particles suspended in a resin; or
a solder paste.

18. The method of claim 11, wherein the external conductive connector comprises a strain-relief connector.

19. The method of claim 18, wherein the strain-relief connector comprises:
an elongated connection member;
a number of curved metal wires, laterally extended from one side of the elongated connection member; and
a number of connection pads.

20. The method of claim 19, wherein attaching the external conductive connector comprises applying the ECA paste between the connection pads and the busbar, forming an electrical and mechanical bond.
